(19) United States
(12) Patent Application Publication
(10) Pub. No.: US 2016/0040287 A1
(43) Pub. Date: Feb. 11, 2016

(54) Tungsten Film Forming Method

(71) Applicant: TOKYO ELECTRON LIMITED, Tokyo (JP)

(72) Inventors: Yasushi AKASAKA, Nirasaki City (JP); Takanobu HOTTA, Nirasaki City (JP); Yasushi AIBA, Nirasaki City (JP)

(21) Appl. No.: 14/819,867

(22) Filed: Aug. 6, 2015

(30) Foreign Application Priority Data
Aug. 11, 2014 (JP) 2014-163501

(51) Int. Cl. C23C 16/455; C23C 16/06

(52) U.S. Cl. CPC C23C 16/45525; C23C 16/06

(57) ABSTRACT

A tungsten film forming method includes forming a tungsten film on a surface of a substrate to be processed by sequentially supplying a WCl₆ gas as a tungsten source gas, a reducing gas composed of a reducible gas including hydrogen and a purge gas into a chamber which accommodates the substrate and which remains in a depressurized atmosphere. A Cl₂ gas is simultaneously supplied when supplying the WCl₆ gas.

### CROSS-REFERENCE TO RELATED APPLICATION

This application claims the benefit of Japanese Patent Application No. 2014-163501, filed on Aug. 11, 2014, in the Japan Patent Office, the disclosure of which is incorporated herein in its entirety by reference.

### TECHNICAL FIELD

The present disclosure relates to a tungsten film forming method.

### BACKGROUND

When manufacturing an LSI (Large Scale Integration), tungsten is widely used in a gate electrode of a MOSFET (Metal Oxide Silicon Field Effect Transistor), contact between a source and a drain, a word line of a memory, etc. In a multi-layer wiring process, a copper wiring is mainly used. However, the copper wiring is insufficient in heat resistance. A tungsten wiring is used particularly in a region which requires a heat resistance at 500 degrees C. or more, a region where deterioration of electrical characteristics due to diffusion of copper is concerned when copper is used near a transistor, etc.

A physical vapor deposition (PVD) method has been used in a tungsten film forming process in the art. However, in a region which requires high step coverage, it may be difficult for the PVD method to achieve the high step coverage. For this reason, film formation has been performed using a chemical vapor deposition (CVD) method which is capable of achieving sufficient miniaturization of devices.

In a tungsten film (CVD-tungsten film) forming method using the CVD method, for example, a tungsten hexafluoride (WF₆) gas as a source gas and an H₂ gas as a reducing gas are generally used to cause reaction of WF₆+3H₂→W+6HF on a wafer.

However, in the case where a CVD-tungsten film is formed using a WF₆ gas, fluorine contained in the WF₆ gas reduces a gate insulation film particularly in a gate electrode or a memory word line of a semiconductor device. Thus, deterioration of electrical characteristics is of great concern. In view of this, forming a CVD-tungsten film using fluorine-free tungsten hexachloride (WCl₆) gas as a source gas has been studied. Chlorine also has reducibility. However, chlorine is weaker in reactivity than fluorine. Thus, it is expected that chlorine has a less adverse effect on electrical characteristics.

In recent years, miniaturization of semiconductor devices is underway. This makes it difficult to achieve good step coverage even in a CVD method which is known to achieve good step coverage. With a view to achieving higher step coverage, attention is paid to an atomic layer deposition (ALD) method in which a source gas and a reducing gas are sequentially supplied with purging interposed therebetween.

However, when a tungsten film is formed by an ALD method using a WCl₆ gas as a source gas and an H₂ gas as a reducing gas, there is a problem in that the thickness of a film deposited per one cycle becomes smaller and the time it takes to deposit a film having a desired thickness.

### SUMMARY

Some embodiments of the present disclosure provide a tungsten film forming method capable of forming a tungsten film at a sufficient deposition rate when forming the tungsten film by sequential gas supply using a WCl₆ gas as a source gas.

According to one embodiment of the present disclosure, a tungsten film forming method includes forming a tungsten film on a surface of a substrate to be processed by sequentially supplying a WCl₆ gas as a tungsten source gas, a reducing gas composed of a reducible gas including hydrogen and a purge gas into a chamber which accommodates the substrate and which remains in a depressurized atmosphere. A Cl₂ gas is simultaneously supplied when supplying the WCl₆ gas.

According to another embodiment of the present disclosure, a tungsten film forming method includes forming a tungsten film on a surface of a substrate to be processed by sequentially supplying a WCl₆ gas as a tungsten source gas, a reducing gas composed of a reducible gas including hydrogen and a purge gas into a chamber which accommodates the substrate and which remains in a depressurized atmosphere. The reducing gas is simultaneously supplied when supplying the WCl₆ gas, or the WCl₆ gas is supplied in a state in which the reducing gas exists within the chamber.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view illustrating one example of a film forming apparatus for implementing a film forming method according to a first embodiment of the present disclosure.

FIG. 2 is a timing chart illustrating a gas supply sequence of the film forming method according to the first embodiment.

FIG. 3 is a sectional view illustrating another example of a film forming apparatus for implementing the film forming method according to the first embodiment of the present disclosure.

FIG. 4 is a sectional view illustrating one example of a film forming apparatus for implementing a film forming method according to a second embodiment of the present disclosure.

FIG. 5 is a timing chart illustrating a gas supply sequence of the film forming method according to the second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

The present inventors studied the reason why a deposition rate is low when a tungsten film is formed by ALD method using a WCl₆ gas as a source gas. As a result, it is postulated that the supplied WCl₆ gas reacts with the tungsten film, which has been already formed, to form sub-chloride (WClₓ (x<6)) such as WCl₅, WCl₄, WCl₂, etc., such that the tungsten film is etched.

The present inventors further studied and found that such an etching is effectively suppressed by supplying a Cl₂ gas which can suppress the formation of sub-chloride (WClₓ (x<6)) and a reducing gas simultaneously when supplying the WCl₆ gas, and completed the present disclosure.

### First Embodiment

First, descriptions will be made on a first embodiment.

[Example of Film Forming Apparatus]

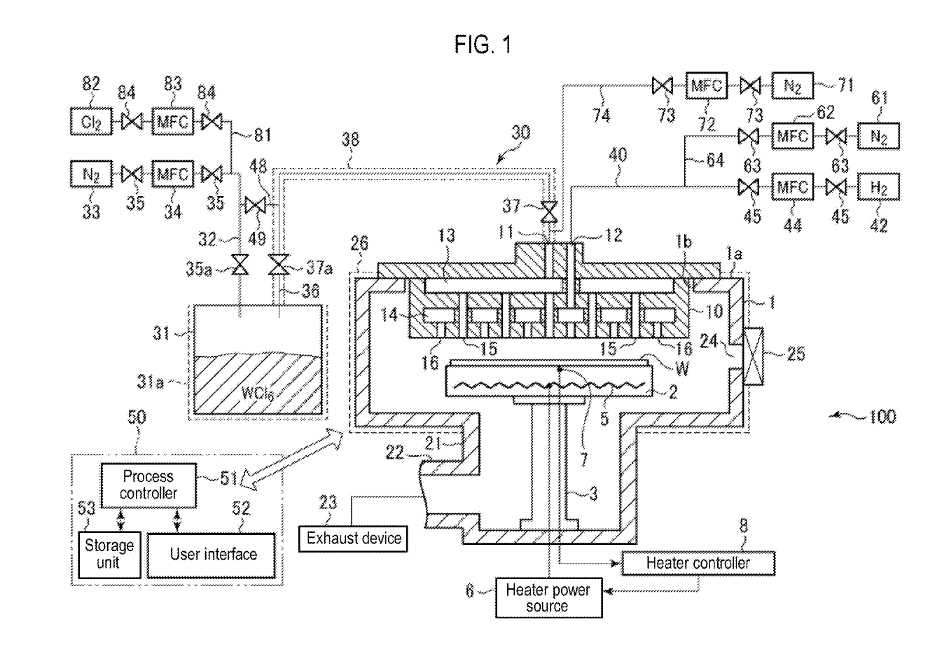

FIG. 1 is a sectional view illustrating one example of a film forming apparatus for implementing a tungsten film forming method according to a first embodiment of the present disclosure.

Referring to FIG. 1, a film forming apparatus 100 includes a substantially cylindrical chamber 1 configured to maintain air-tightness, in which a susceptor 2 configured to support a substrate to be processed, that is, a wafer W, in a horizontal state is supported by a cylindrical support member 3 extending from a bottom of an exhaust chamber described below to a lower portion center of the susceptor 2. The susceptor 2 is made of a ceramic material, for example, MN and the like. In addition, a heater 5 is embedded in the susceptor 2 and is connected to a heater power source 6. On the other hand, a thermocouple 7 is disposed near an upper surface of the susceptor 2 and is configured to allow signals of the thermocouple 7 to be sent to a heater controller 8. Further, the heater controller 8 sends a command to the heater power source 6 in response to a signal from the thermocouple 7 to control heating of the heater 5 such that the wafer W has a desired temperature. Further, the susceptor 2 is provided with three wafer lifting pins (not shown), which can protrude or be retracted with respect to the surface of the susceptor 2, such that the wafer lifting pins protrude from the surface of the susceptor 2 during delivery of the wafer W. Further, the susceptor 2 is movable up and down by a lift mechanism (not shown).

A ceiling wall 1a of the chamber 1 is formed with a circular opening 1b, through which a showerhead 10 is inserted to protrude into the chamber 1. The showerhead 10 is configured to inject a WCl₆ gas, which is a film formation source gas supplied from a gas supply mechanism 30 described below, into the chamber 1, and is provided at an upper portion thereof with a first introduction channel 11 for introducing the WCl₆ gas and an N₂ gas as a purge gas, and with a second introduction channel 12 for introducing an H₂ gas as a reducing gas and an N₂ gas as a purge gas.

The showerhead 10 has upper and lower spaces 13 and 14 therein. The first introduction channel 11 is connected to the upper space 13 and a first gas injection channel 15 extends from the upper space 13 to a lower surface of the showerhead 10. The second introduction channel 12 is connected to the lower space 14 and a second gas injection channel 16 extends from the lower space 14 to the lower surface of the showerhead 10. That is to say, the showerhead 10 is configured to allow the WCl₆ gas as the film formation source gas and the H₂ gas as the reducing gas to be independently injected through the first and second injection channels 15 and 16, respectively.

The chamber 1 is provided at a bottom wall thereof with an exhaust chamber 21 protruding downwards. The exhaust chamber 21 is connected at a side surface thereof to an exhaust pipe 22, to which an exhaust device 23 including a vacuum pump, a pressure control valve and the like are connected. An interior of the chamber 1 can be maintained in a predetermined depressurized state by operation of the exhaust device 23.

A sidewall of the chamber 1 is provided with a transfer gate 24 through which the wafer W is transferred, and a gate valve 25 for opening and closing the transfer gate 24. Furthermore, a heater 26 is provided in a wall portion of the chamber 1 to control the temperature of an inner wall of the chamber 1 during film formation.

The gas supply mechanism 30 includes a film formation source tank 31 which accommodates WCl₆ as a film formation source. WCl₆ has a solid phase at room temperature, and WCl₆ in a solid state is accommodated in the film formation source tank 31. A heater 31a is installed around the film formation source tank 31 and is configured to heat the film formation source accommodated in the film formation source tank 31 to a suitable temperature so as to sublimate WCl₆.

A carrier gas pipe 32 for supplying a carrier gas from above is inserted into the film formation source tank 31. An N₂ gas is supplied from an N₂ gas supply source 33 to the carrier gas pipe 32. Furthermore, a Cl₂ gas supply pipe 81 is connected to the carrier gas pipe 32. A Cl₂ gas is supplied from a Cl₂ gas supply source 82 to the Cl₂ gas supply pipe 81. Accordingly, the N₂ gas and the Cl₂ gas as the carrier gases are supplied to the film formation source tank 31 through the carrier gas pipe 32. A mass flow controller 34 as a flow rate controller and valves 35 disposed at both sides of the mass flow controller 34 are mounted to the carrier gas pipe 32. A mass flow controller 83 and valves 84 disposed at both sides of the mass flow controller 83 are mounted to the Cl₂ gas supply pipe 81. This makes it possible to supply the N₂ gas and the Cl₂ gas as the carrier gases at a desired flow rate ratio. Alternatively, only the Cl₂ gas may be supplied as the carrier gas.

A source gas supply pipe 36 which becomes a source gas line is inserted into the film formation source tank 31 from above. The source gas supply pipe 36 is connected at the other end thereof to the first introduction channel 11 of the showerhead 10. A valve 37 is mounted to the source gas supply pipe 36. A heater 38 for preventing condensation of the WCl₆ gas as the film formation source gas is installed in the source gas supply pipe 36.

The WCl₆ gas sublimated within the film formation source tank 31 is transferred to the source gas supply pipe 36 by the N₂ gas and the Cl₂ gas as the carrier gases supplied from the carrier gas pipe 32 into the film formation source tank 31 and is supplied into the showerhead 10 via the first introduction channel 11.

Furthermore, an N₂ gas supply source 71 is connected to the source gas supply pipe 36 via a bypass pipe 74. A mass flow controller 72 as a flow rate controller and valves 73 disposed at both sides of the mass flow controller 72 are mounted to the bypass pipe 74. An N₂ gas supplied from the N₂ gas supply source 71 is used as a purge gas at the source gas line.

Furthermore, a bypass pipe 48 is disposed between the carrier gas pipe 32 and the source gas supply pipe 36 and is provided with a valve 49. Valves 35a and 37a are placed at downstream sides of connection portions of the bypass pipe 48 to the carrier gas pipe 32 and the source gas supply pipe 36, respectively. Thus, by closing the valves 35a and 37a while opening the valve 49, the N₂ gas supplied from the N₂ gas source 33 can be purged to the source gas supply pipe 36 through the carrier gas pipe 32 and the bypass pipe 48. Here, other inert gases including Ar gas may be used as the carrier gas and the purge gas without being limited to the N₂ gas.

The second introduction channel 12 of the showerhead 10 is connected to a pipe 40 as an H₂ gas line, and the pipe 40 is connected to an H₂ gas supply source 42, which supplies an H₂ gas as a reducing gas, and to an N₂ gas supply source 61 through a bypass pipe 64. Further, the pipe 40 is provided with a mass flow controller 44 as a flow rate controller and valves 45 disposed at both sides of the mass flow controller 44, and the bypass pipe 64 is provided with a mass flow controller 62 as a flow rate controller and valves 63 disposed at both sides of the mass flow controller 62. An N₂ gas supplied from the N₂ gas supply source 61 is used as a purge gas at the H₂ gas line.

The reducing gas is not limited to the H₂ gas but may be a reducible gas including hydrogen. In addition to the H₂ gas, it may be possible to use an SiH₄ gas, a B₂H₆ gas, an NH₃ gas and the like, two or more of which may be used in combination.

The film forming apparatus 100 includes a controller 50 configured to control various components, specifically, valves, a power source, heaters, pumps, and the like. The controller 50 includes a process controller 51 including a microprocessor (computer), a user interface 52, and a storage part 53. The process controller 51 is electrically connected to the various components of the film forming apparatus 100 and is configured to control the same. The user interface 52 is connected to the process controller 51 and is composed of a keyboard, by which an operator performs a command input operation and the like to manage the respective components of the film forming apparatus 100, a display configured to visualize and display operating states of the respective components of the film forming apparatus 100, and the like. The storage part 53 is also connected to the process controller 51, and stores control programs configured to realize various processes executed in the film forming apparatus 100 by control of the process controller 51, control programs configured to execute a certain process in each component of the film forming apparatus 100 based on process conditions, that is, process recipes, various databases, and the like. The process recipes are stored in a non-transitory storage medium (not shown) in the storage part 53. The storage medium may include a fixedly-installed storage medium such as a hard disk, or a portable storage medium such as a CDROM, DVD, flash memory, and the like. Alternatively, the process recipes may be appropriately transferred from another apparatus, for example, through a dedicated line.

In addition, the process recipes are read out from the storage part 53 according to an instruction from the user interface 52, as needed, and a process based on the read recipes is then performed by the process controller 51, thereby allowing a desired process to be performed in the film forming apparatus 100 under the control of the process controller 51.

[Film Forming Method]

Next, descriptions will be made on a film forming method according to a first embodiment, which is implemented by the film forming apparatus 100 configured as above.

In this embodiment, a wafer including a barrier metal film formed as a base film on, for example, a surface of a thermal oxide film or a surface of an interlayer insulating film having depressions such as trenches or holes is used to form a tungsten film on a surface of the wafer.

In film formation, the gate valve 25 is first opened. A wafer W is carried into the chamber 1 through the transfer gate 24 by a transfer device (not illustrated) and is mounted on the susceptor 2 heated to a predetermined temperature by the heater 5. The chamber 1 is depressurized to a predetermined vacuum level. Thereafter, the valves 37, 37a and 45 are closed and the valves 63 and 73 are opened. Thus, the N₂ gas (a purge gas at the source gas line and a purge gas at the H₂ gas line) is supplied from the N₂ gas supply sources 61 and 71 into the chamber 1, thereby increasing the internal pressure of the chamber 1. The temperature of the wafer W mounted on the susceptor 2 is stabilized. After the internal pressure of the chamber 1 reaches a predetermined pressure, formation of a tungsten film is performed by sequential gas supply in the following manner.

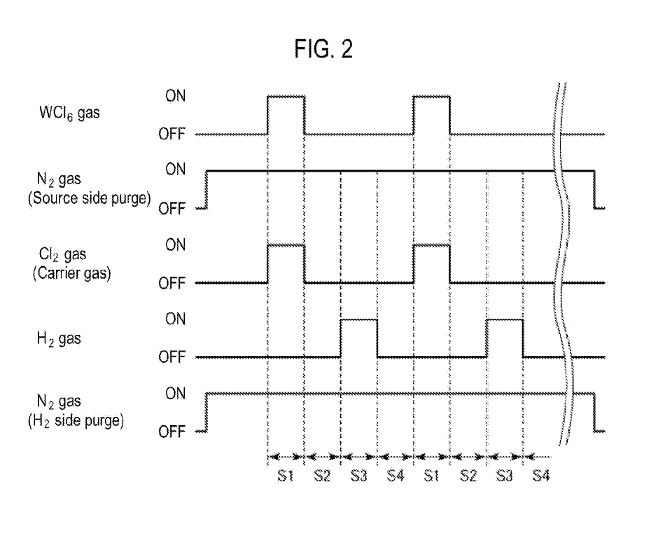

FIG. 2 is a timing chart illustrating a gas supply sequence of the film forming method according to the first embodiment.

First, the valves 37 and 37a are opened while allowing the N₂ gas to flow from the N₂ gas supply sources 61 and 71. Thus, the N₂ gas and the Cl₂ gas as the carrier gases are supplied into the film formation source tank 31. The WCl₆ gas sublimated within the film formation source tank 31 is supplied into the chamber 1 by the N₂ gas and the Cl₂ gas (Step S1). Consequently, WCl₆ is adsorbed onto the surface of the wafer W. At step S1, in addition to the WCl₆ gas, the Cl₂ gas as the carrier gas is also supplied into the chamber 1.

Subsequently, the valves 37 and 37a are closed to stop the supply of the WCl₆ gas and the Cl₂ gas. Only the N₂ gas as the purge gas is supplied into the chamber 1, thereby purging the excessive WCl₆ gas existing within the chamber 1 (Step S2).

Subsequently, the valve 45 is opened while allowing the N₂ gas to flow from the N₂ gas supply sources 61 and 71, whereby the H₂ gas as the reducing gas is supplied from the H₂ gas supply source 42 into the chamber 1 (Step S3). Consequently, WCl₆ adsorbed onto the wafer W is reduced.

Subsequently, the valve 45 is closed to stop the supply of the H₂ gas. Only the N₂ gas as the purge gas is supplied into the chamber 1, thereby purging the excessive H₂ gas existing within the chamber 1 (Step S4).

A thin unit tungsten film is formed by one cycle including Steps S1 to S4 described above. Then, a tungsten film having a desired thickness may be formed by repeating the cycle including these steps a plurality times. The thickness of the tungsten film may be controlled by adjusting the number of repetitions of the cycle.

By the gas supply sequence of the first embodiment described above, it is possible to solve the problem that the deposition rate of a tungsten film is low in the ALD method.

The reasons for this will now be described. WCl₅ or the like as sub-chloride exists in WCl₆ used as a tungsten source gas. It is known that WCl₅ is higher in vapor pressure than WCl₆. In a WCl₆ gas adsorption step of the ALD method, only a WCl₆ gas and an N₂ gas are supplied. For that reason, the reaction of the following formula (1) occurs and the tungsten film deposited so far is etched away.

5WCl₆(g)+W(s)→6WCl₅(g) (1)

Due to this etching reaction, a superficial deposition rate grows lower in the case where a tungsten film is deposited by the ALD method using a WCl₆ gas.

In the meantime, the reaction by which WCl₅ as a sub-chloride is generated from WCl₆ is as represented by the following formula (2).

WCl₆→WCl₅+(½)Cl₂ (2)

Accordingly, the partial pressure of a (½)Cl₂ gas may be increased in order to suppress decomposition of WCl₆ and to suppress etching of tungsten.

Thus, in the present embodiment, when supplying the WCl₆ gas into the chamber 1, the Cl₂ gas is also supplied to suppress decomposition of WCl₆. Consequently, the etching reaction of tungsten caused by WCl₆ is suppressed. This makes it possible to form a tungsten film at a sufficiently-high deposition rate using WCl₆ as the film formation source. As a result, it is possible to cost-effectively provide a tungsten film which is free from deterioration of electrical characteristics otherwise caused by fluorine.

As described above, the Cl₂ gas is used as a carrier gas when supplying the WCl₆ gas. The method of supplying the Cl₂ gas is a novel method not employed in the related art. Furthermore, the method of suppressing the etching of the tungsten film by supplying the Cl₂ gas simultaneously with the supply of the WCl₆ gas and eventually increasing the partial pressure of the Cl₂ gas in this way is effective regardless of the film forming method.

(Film Forming Condition)

While film forming conditions used in this case are not particularly limited, the following conditions may be suitable.

Wafer temperature (surface temperature of susceptor): 400 to 600 degrees C.

Internal pressure of chamber: 1 to 80 Torr (133 to 10,640 Pa)

Flow rate of carrier gases (N₂+Cl₂): 100 to 2,000 sccm (mL/min)

(Supply amount of WCl₆ gas: 5 to 100 sccm (mL/min))

Flow rate of Cl₂ gas: 1 to 100 sccm (mL/min)

Time period of Step S1 (per one time): 0.01 to 5 sec

Flow rate of H₂ gas: 500 to 5,000 sccm (mL/min)

Time period of Step S3 (per one time): 0.1 to 5 sec

Time period of Steps S2 and S4 (purge) (per one time): 0.1 to 5 sec

Heating temperature of film formation source tank: 130 to 170 degrees C.

Furthermore, the reducing gas may be a reducible gas including hydrogen. In addition to the H₂ gas, it may be possible to use an SiH₄ gas, a B₂H₆ gas, an NH₃ gas and the like. Even in the case where these gases are used, it is possible to perform desirable film formation under similar conditions. With a view to reducing impurities within a film and obtaining a low resistance value, it is preferable in some embodiments to use the H₂ gas.

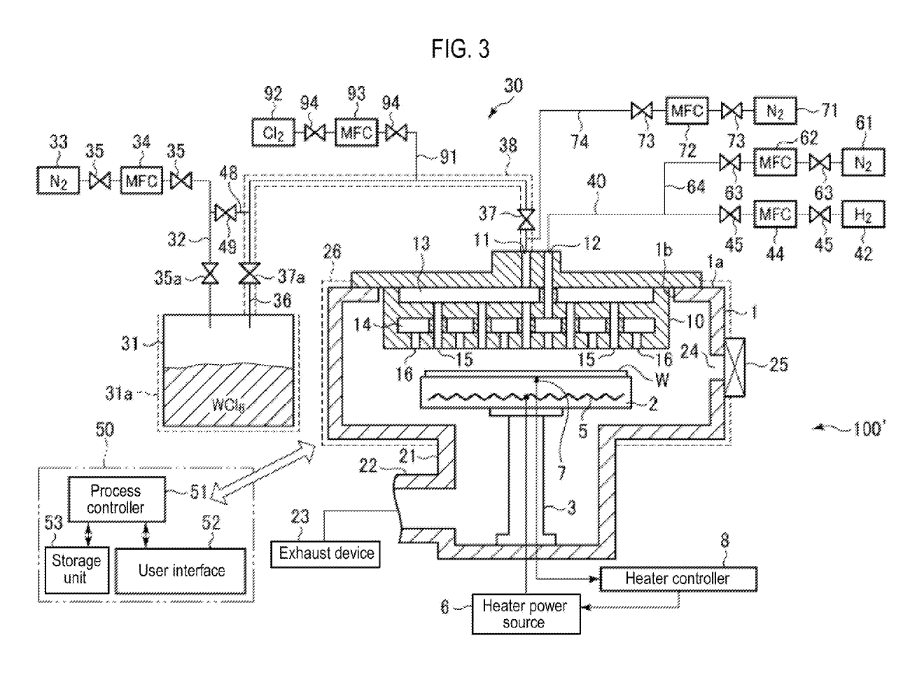

Furthermore, the Cl₂ gas may be supplied through a separate line instead of supplying the same as the carrier gas for the WCl₆ gas. This example is illustrated in FIG. 3. In a film forming apparatus 100′ illustrated in FIG. 3, instead of connecting the Cl₂ gas supply pipe 81 to the carrier gas pipe 32, a Cl₂ gas supply pipe 91 is connected to the source gas supply pipe 36. The Cl₂ gas is supplied from a Cl₂ gas supply source 92 to the Cl₂ gas supply pipe 91. Thus, the Cl₂ gas is supplied to the chamber 1 together with the WCl₆ gas supplied to the source gas supply pipe 36. A mass flow controller 93 and valves 94 disposed at both sides of the mass flow controller 93 are mounted to the Cl₂ gas supply pipe 91. Other configurations of the film forming apparatus 100′ illustrated in FIG. 3 are the same as those of the film forming apparatus 100 illustrated in FIG. 1.

### Second Embodiment

Next, descriptions will be made on a second embodiment.

[Example of Film Forming Apparatus]

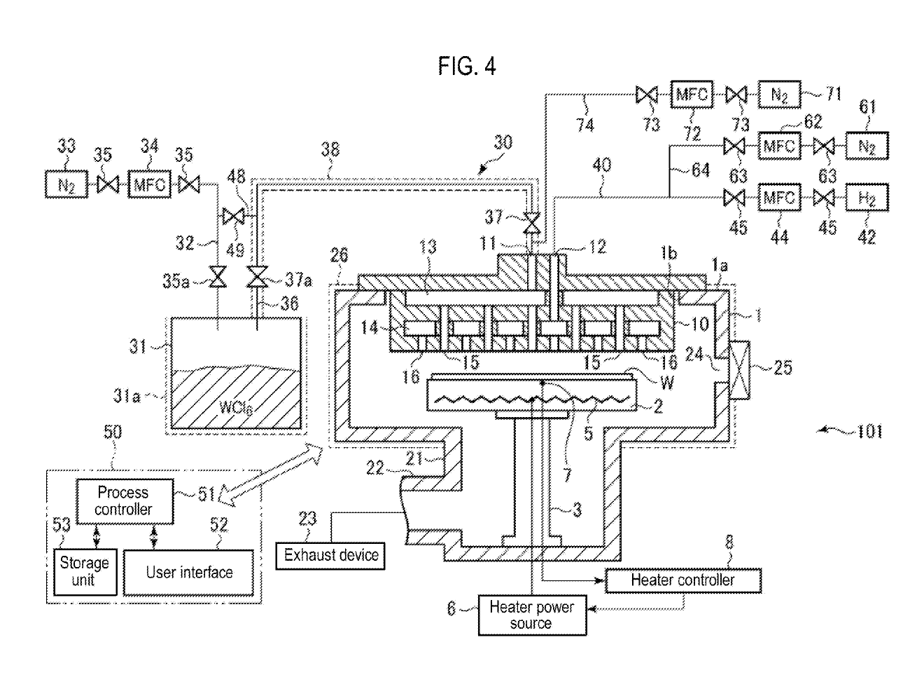

FIG. 4 is a sectional view illustrating one example of a film forming apparatus for implementing a film forming method according to a second embodiment of the present disclosure. A film forming apparatus 101 illustrated in FIG. 4 is not provided with the Cl₂ gas supply pipe 81 and the Cl₂ gas supply source 82. Accordingly, only the N₂ gas is used as the carrier gas for the WCl₆ gas. Except for this point, the film forming apparatus 101 is completely identical in configuration with the film forming apparatus 100 illustrated in FIG. 1. Therefore, identical components are designated by the same reference symbols as used in FIG. 1, with the descriptions thereof omitted.

[Film Forming Method]

Next, descriptions will be made on a film forming method according to a second embodiment, which is implemented using the film forming apparatus 101 configured as above.

Even in the present embodiment, similar to the first embodiment, a wafer including a barrier metal film formed as a base film on, for example, a surface of a thermal oxide film or a surface of an interlayer insulating film having depressions such as trenches or holes is used to form a tungsten film on a surface of the wafer.

Even in the present embodiment, during film formation, the gate valve 25 is first opened. A wafer W is carried into the chamber 1 through the transfer gate 24 by a transfer device (not illustrated) and is mounted on the susceptor 2 heated to a predetermined temperature by the heater 5. The chamber 1 is depressurized to a predetermined vacuum level. Thereafter, the valves 37, 37a and 45 are closed and the valves 63 and 73 are opened. Thus, the N₂ gas (a purge gas at the source gas line and a purge gas at the H₂ gas line) is supplied from the N₂ gas supply sources 61 and 71 into the chamber 1, thereby increasing the internal pressure of the chamber 1. The temperature of the wafer W mounted on the susceptor 2 is stabilized. After the internal pressure of the chamber 1 reaches a predetermined pressure, formation of a tungsten film is performed by sequential gas supply in the following manner.

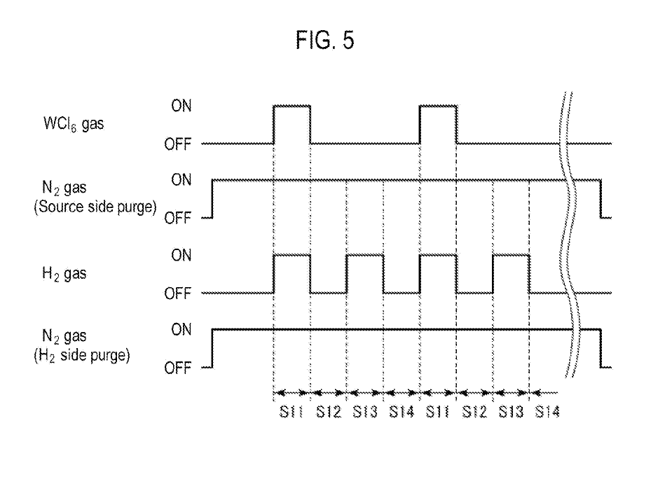

FIG. 5 is a timing chart illustrating a gas supply sequence of the film forming method according to the second embodiment.

First, the valves 37 and 37a are opened while allowing the N₂ gas to flow from the N₂ gas supply sources 61 and 71. Thus, the N₂ gas as the carrier gas is supplied into the film formation source tank 31. The WCl₆ gas sublimated within the film formation source tank 31 is supplied into the chamber 1 by the carrier gas. Moreover, the valve 45 is opened to supply an H₂ gas at a predetermined flow rate from the H₂ gas supply source 42 into the chamber 1 (Step S11). Consequently, WCl₆ is adsorbed onto the surface of the wafer W.

Subsequently, the valves 37 and 37a and the valve 45 are closed to stop the supply of the WCl₆ gas and the H₂ gas. Only the N₂ gas as the purge gas is supplied into the chamber 1, thereby purging the excessive WCl₆ gas and the excessive H₂ gas existing within the chamber 1 (Step S12).

Subsequently, the valve 45 is opened while allowing the N₂ gas to flow from the N₂ gas supply sources 61 and 71, whereby the H₂ gas as the reducing gas is supplied from the H₂ gas supply source 42 into the chamber 1 (Step S13). Consequently, WCl₆ adsorbed onto the wafer W is reduced.

Subsequently, the valve 45 is closed to stop the supply of the H₂ gas. Only the N₂ gas as the purge gas is supplied into the chamber 1, thereby purging the excessive H₂ gas existing within the chamber 1 (Step S14).

A thin unit tungsten film is formed by one cycle including Steps S11 to S14 described above. Then, a tungsten film having a desired thickness may be formed by repeating the cycle including these steps a plurality times. The thickness of the tungsten film may be controlled by adjusting the number of repetitions of the cycle.

By the gas supply sequence of the second embodiment described above, it is possible to solve the problem of the low deposition rate of a tungsten film in the ALD method.

That is to say, in a WCl₆ gas adsorption step of the ALD method, only a WCl₆ gas and an N₂ gas are supplied. For that reason, the etching reaction of a tungsten film occurs as represented by the foregoing formula (1). However, by supplying the WCl₆ gas and the H₂ gas used as a reducing gas, a tungsten production reaction occurs. It is therefore possible to prevent etching of a tungsten film. This makes it possible to form a tungsten film at a sufficiently-high deposition rate using WCl₆ as the film formation source. As a result, it is possible to cost-effectively provide a tungsten film which is free from deterioration of electrical characteristics otherwise caused by fluorine.

The flow rate of the H₂ gas at Step S11 may be set so as to effectively suppress the etching reaction of tungsten and may be set smaller than the flow rate of the H₂ gas to reduce the WCl₆ gas at Step S13.

(Film Forming Condition)

While film forming conditions used in this case are not particularly limited, the following conditions may be suitable.

Wafer temperature (susceptor surface temperature): 400 to 600 degrees C.

Internal pressure of chamber: 1 to 80 Torr (133 to 10,640 Pa)

Flow rate of carrier gas: 100 to 2,000 sccm (mL/min)

(Supply amount of WCl₆ gas: 5 to 100 sccm (mL/min))

Flow rate of H₂ gas at Step S11: 1 to 500 sccm (mL/min)

Time period of Step S11 (per one time): 0.01 to 5 sec

Flow rate of H₂ gas at Step S13: 500 to 5,000 sccm (mL/min)

Time period of Step S13 (per one time): 0.1 to 5 sec

Time period of Steps S12 and S14 (purge) (per one time): 0.1 to 5 sec

Heating temperature of film formation source tank: 130 to 170 degrees C.

Instead of supplying the H₂ gas simultaneously with the supply of the WCl₆ gas, it may be possible to supply the WCl₆ gas in a state in which the H₂ gas remains within the chamber 1. Even in the present embodiment, the reducing gas may be a reducible gas including hydrogen. In addition to the H₂ gas, it may be possible to use an SiH₄ gas, a B₂H₆ gas, an NH₃ gas and the like. Even in the case where these gases are used, it is possible to perform desirable film formation under similar conditions. With a view to reducing impurities within a film and obtaining a low resistance value, it is preferable in some embodiments to use the H₂ gas. The gas supplied together with the WCl₆ gas is not limited to H₂ gas but may be any reducible gas that includes hydrogen. In some embodiment, the gas supplied together with the WCl₆ gas may be the same as the gas used as the reducing gas. However, in another embodiment, the gas supplied together with the WCl₆ gas may differ from the gas used as the reducing gas, as long as the gas supplied together with the WCl₆ gas is a reducible gas including hydrogen.

<Semiconductor Device>

If a semiconductor device is manufactured by using the tungsten film forming method of the first embodiment or the second embodiment in forming a tungsten film used in a gate electrode of a MOSFET, contact between a source and a drain, a word line of a memory, etc., it is possible to efficiently and cost-effectively manufacture a semiconductor device having improve characteristics.

<Other Applications>

It should be understood that the present disclosure is not limited to the aforementioned embodiments and may be modified in various ways. For example, in the aforementioned embodiments, the present disclosure has been described by way of an example wherein a semiconductor wafer is used as a substrate to be processed. However, the semiconductor wafer may be a silicon semiconductor or compound semiconductors made of, e.g., GaAs, SiC, GaN, and the like. In addition, the present disclosure is not limited to the semiconductor wafer, and may be applied to glass substrates used in flat panel displays (FPDs) for liquid crystal displays and the like, ceramic substrates, and the like.

According to the present disclosure in some embodiments, when a tungsten film is formed on a surface of a substrate to be processed by sequentially supplying a WCl₆ gas as a tungsten source gas, a reducing gas composed of a reducible gas including hydrogen and a purge gas, a Cl₂ gas is supplied together with the WCl₆ gas. Alternatively, the reducing gas may be simultaneously supplied when supplying the WCl₆ gas. Alternatively, the reducing gas may be allowed to exist within the chamber. It is therefore possible to suppress etching of the tungsten film when supplying the WCl₆ gas and to form the tungsten film at a sufficiently-high deposition rate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A tungsten film forming method, comprising:
forming a tungsten film on a surface of a substrate to be processed by sequentially supplying a WCl₆ gas as a tungsten source gas, a reducing gas composed of a reducible gas including hydrogen and a purge gas into a chamber which accommodates the substrate and which remains in a depressurized atmosphere,
wherein a Cl₂ gas is simultaneously supplied when supplying the WCl₆ gas.

2. The method of claim 1, wherein a tungsten unit film is formed by a cycle including:
supplying the WCl₆ gas and the Cl₂ gas into the chamber;
purging an interior of the chamber;
supplying the reducing gas into the chamber; and
purging the interior of the chamber, and
wherein a tungsten film having a desired thickness is formed by repeating the cycle a plurality of times.

3. The method of claim 1, wherein the WCl₆ gas is transferred into the chamber by supplying a carrier gas to a solid-state WCl₆ source, and the Cl₂ gas is supplied into the chamber simultaneously with the supply of the WCl₆ gas by using the Cl₂ gas as at least a part of the carrier gas.

4. A tungsten film forming method, comprising:
forming a tungsten film on a surface of a substrate to be processed by sequentially supplying a WCl₆ gas as a tungsten source gas, a reducing gas composed of a reducible gas including hydrogen and a purge gas into a chamber which accommodates the substrate and which remains in a depressurized atmosphere,
wherein the reducing gas is simultaneously supplied when supplying the WCl₆ gas, or the WCl₆ gas is supplied in a state in which the reducing gas exists within the chamber.

5. The method of claim 4, wherein a tungsten unit film is formed by a cycle including:
supplying the WCl₆ gas and the reducing gas into the chamber;
purging an interior of the chamber;
supplying the reducing gas into the chamber;
purging the interior of the chamber, and
wherein a tungsten film having a desired thickness is formed by repeating the cycle a plurality of times.

6. The method of claim 1, wherein the reducing gas is at least one selected from a group consisting of an H₂ gas, an SiH₄ gas, a B₂H₆ gas and an NH₃ gas.
